(19) United States
(12) Patent Application Publication
(10) Pub. No.: US 2025/0046749 A1
(43) Pub. Date: Feb. 6, 2025

(54) SEMICONDUCTOR PACKAGE

(71) Applicant: Samsung Electronics Co., Ltd., Suwon-si (KR)

(72) Inventors: Hyunsoo Chung, Suwon-si (KR); Kwangsoo Kim, Suwon-si (KR); Inhyo Hwang, Suwon-si (KR)

(21) Appl. No.: 18/783,805

(22) Filed: Jul. 25, 2024

(30) Foreign Application Priority Data
Aug. 3, 2023 (KR) 10-2023-0101791

(51) Int. Cl. H01L 23/00; H01L 23/31; H01L 23/498; H01L 23/538; H01L 25/18; H10B 80/00

(52) U.S. Cl. CPC H01L 24/32; H01L 23/31; H01L 23/49822; H01L 23/49838; H01L 23/5386; H01L 24/29; H01L 24/16; H01L 24/73; H01L 25/18; H01L 2224/16145; H01L 2224/16227; H01L 2224/29187; H01L 2224/32145; H01L 2224/32225; H01L 2224/73204; H01L 2924/1431; H01L 2924/1436; H10B 80/00

(57) ABSTRACT

A semiconductor package includes an interposer; a plurality of semiconductor devices that are on the interposer and spaced apart from each other; and a package underfill layer that includes a first underfill layer in a first gap that is between the plurality of semiconductor devices and a second underfill layer in a second gap that is between the plurality of semiconductor devices and the interposer, where the second underfill layer includes a second underfill layer side surface that faces a lateral direction, where the second underfill layer side surface does not contact the plurality of semiconductor devices and a portion of the interposer that is adjacent to the second gap, where the second underfill layer side surface extends between a top surface of the interposer and bottom surfaces of the plurality of semiconductor devices and extends from a lower outer boundary.

### CROSS-REFERENCE TO RELATED APPLICATION

This application is based on and claims priority under 35 U.S.C. § 119 to Korean Patent Application No. 10-2023-0101791, filed on Aug. 3, 2023, in the Korean Intellectual Property Office, the disclosure of which is incorporated by reference herein in its entireties.

### TECHNICAL FIELD

The present disclosure relates to a semiconductor package.

### BACKGROUND

Based on the rapid development of the electronics industry, electronic devices have become further miniaturized, multi-functionalized, and have increased in capacity. Accordingly, a semiconductor package including a plurality of semiconductor chips may be desired. As semiconductors are highly integrated, printed circuit boards may not be able to accommodate such high integration, and in this regard, a semiconductor package structure in which an interposer is arranged between a semiconductor chip and a package substrate is used.

### SUMMARY

The present disclosure provides a semiconductor package having improved thermal characteristics and mechanical reliability.

Additional aspects will be set forth in part in the description which follows and, in part, will be apparent from the description, or may be learned by practice of the presented embodiments.

According to an aspect of the present disclosure, a semiconductor package includes an interposer; a plurality of semiconductor devices that are on the interposer and spaced apart from each other; and a package underfill layer that includes a first underfill layer in a first gap that is between the plurality of semiconductor devices and a second underfill layer in a second gap that is between the plurality of semiconductor devices and the interposer, where the second underfill layer includes a second underfill layer side surface that faces a lateral direction, where the second underfill layer side surface does not contact the plurality of semiconductor devices and a portion of the interposer that is adjacent to the second gap, where the second underfill layer side surface extends between a top surface of the interposer and bottom surfaces of the plurality of semiconductor devices and extends from a lower outer boundary, and where the lower outer boundary corresponds to a location in which outer side surfaces of the plurality of semiconductor devices and the bottom surfaces of the plurality of semiconductor devices meet.

According to another aspect of the present disclosure, a semiconductor package includes an interposer that includes a semiconductor substrate, a plurality of through electrodes that extend into the semiconductor substrate, and a rewiring layer; a plurality of semiconductor devices that are on the interposer and spaced apart from each other; a package underfill layer that includes a first underfill layer in a first gap that is between the plurality of semiconductor devices and a second underfill layer in a second gap that is between the plurality of semiconductor devices and the interposer; and a mold member that is on a top surface of the interposer and at least partially surrounds outer side surfaces of the plurality of semiconductor devices, where the second underfill layer includes a second underfill layer side surface that faces a lateral direction, where the second underfill layer side surface does not contact the plurality of semiconductor devices and a portion of the interposer that is adjacent to the second gap, where the second underfill layer side surface extends between the top surface of the interposer and bottom surfaces of the plurality of semiconductor devices and extends from a lower outer boundary, and where the lower outer boundary corresponds to a location in which the outer side surfaces of the plurality of semiconductor devices and the bottom surfaces of the plurality of semiconductor devices meet, and where the plurality of semiconductor devices include a first semiconductor device and a second semiconductor device, where the first semiconductor device includes a logic chip, and where the second semiconductor device includes a plurality of stacked memory chips.

According to another aspect of the present disclosure, a semiconductor package includes an interposer that includes a semiconductor substrate, a plurality of through electrodes that extend into the semiconductor substrate, and a rewiring layer; a plurality of semiconductor devices that are on the interposer and spaced apart from each other; a package underfill layer that includes a first underfill layer in a first gap that is between the plurality of semiconductor devices and a second underfill layer in a second gap that is between the plurality of semiconductor devices and the interposer; and a mold member that is on a top surface of the interposer and at least partially surrounds outer side surfaces of the plurality of semiconductor devices, where the second underfill layer includes a second underfill layer side surface that faces a lateral direction, where the second underfill layer side surface does not contact the plurality of semiconductor devices and a portion of the interposer in the second gap, the second underfill layer side surface extends between the top surface of the interposer and bottom surfaces of the plurality of semiconductor devices and extends from a lower outer boundary, and where the lower outer boundary corresponds to a location in which the outer side surfaces of the plurality of semiconductor devices and the bottom surfaces of the plurality of semiconductor devices meet, where a top surface of the mold member, a top surface of the first underfill layer that is exposed in the first gap, and the top surfaces of the plurality of semiconductor devices are coplanar, where the mold member contacts an entirety of the outer side surfaces of the plurality of semiconductor devices, where the first underfill layer and the second underfill layer are unitary, where the package underfill layer includes an underfill filler, where the underfill filler includes boron nitride (BN) or silica coated aluminum nitride (SCAN), where a first separation width corresponds to a distance between the plurality of semiconductor devices, where the first separation width is greater than a second separation width that corresponds to a distance between the plurality of semiconductor devices and the interposer, and where the plurality of semiconductor devices include a first semiconductor device and a second semiconductor device, where the first semiconductor device includes a logic chip, and where the second semiconductor device includes a plurality of stacked memory chips.

### BRIEF DESCRIPTION OF THE DRAWINGS

Embodiments will be more clearly understood from the following detailed description taken in conjunction with the accompanying drawings in which:

FIG. 1 is a plane layout of a semiconductor package according to an embodiment of the present disclosure;

FIG. 2 is a cross-sectional view of the semiconductor package of FIG. 1 taken along a line I-I′ of FIG. 1 according to an embodiment of the present disclosure;

FIG. 3 is a cross-sectional view of a semiconductor package according to an embodiment of the present disclosure;

FIG. 4 is a cross-sectional view of a semiconductor package according to an embodiment of the present disclosure;

FIG. 5 is a plane layout of a semiconductor package according to an embodiment of the present disclosure;

FIG. 6 is a cross-sectional view of the semiconductor package of FIG. 5 taken along a line II-II′ of FIG. 5 according to an embodiment of the present disclosure;

FIG. 7 is a view for describing a method of manufacturing a semiconductor package according to an embodiment of the present disclosure;

FIG. 8 is a view for describing a method of manufacturing a semiconductor package according to an embodiment of the present disclosure; and

FIG. 9 is a view for describing a method of manufacturing a semiconductor package according to an embodiment of the present disclosure.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the phrase “at least one of A, B, and C” refers to a logical (A OR B OR C) using a non-exclusive logical OR, and should not be construed to mean “at least one of A, at least one of B and at least one of C.” As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction. The term “exposed” may be used to define a relationship between particular layers or surfaces, but it does not require the layer or surface to be free of other elements or layers thereon in the completed device.

Hereinafter, embodiments will be described in detail with reference to accompanying drawings. In the drawings, like reference numerals are used for like elements and redundant descriptions thereof will be omitted.

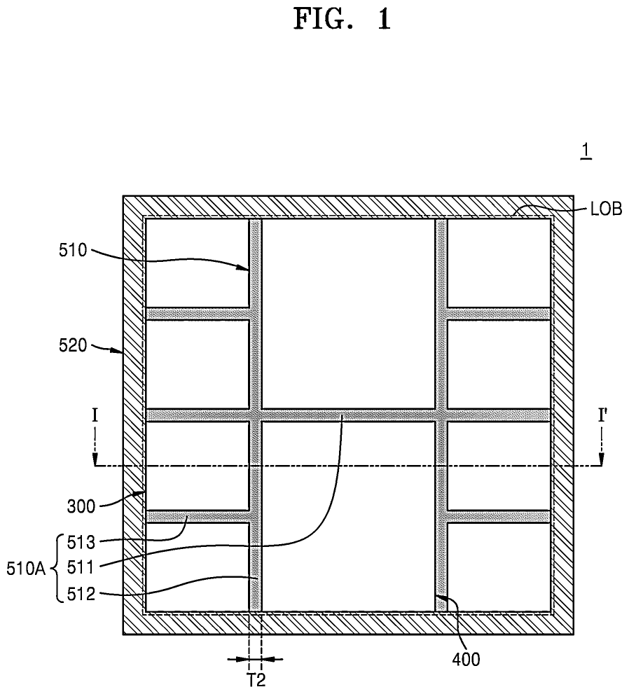

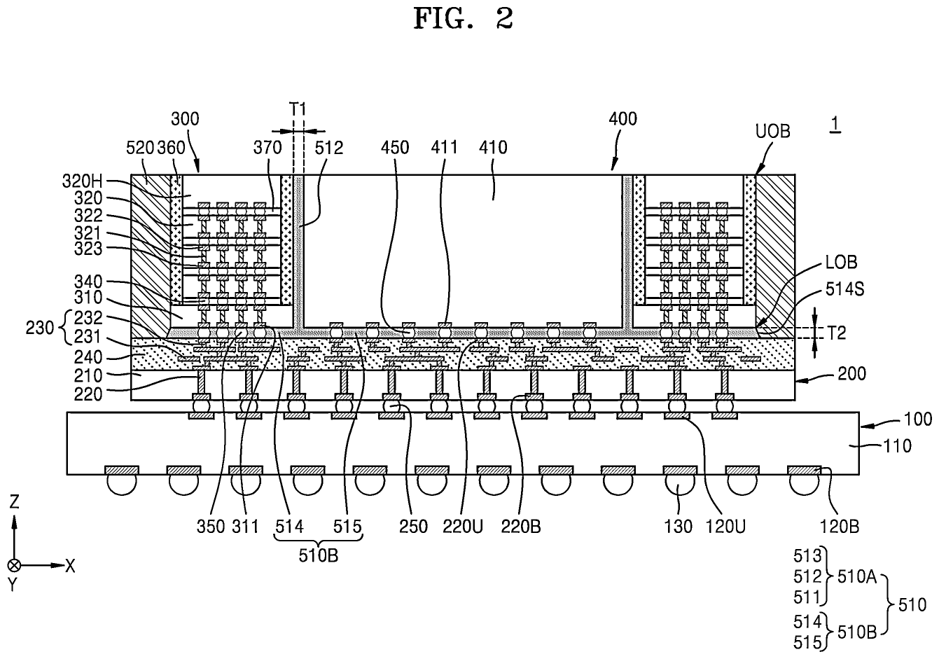

FIG. 1 is a plane layout of a semiconductor package 1 according to an embodiment. FIG. 2 is a cross-sectional view of the semiconductor package 1 of FIG. 1 taken along a line I-I′ of FIG. 1 according to an embodiment.

Referring to FIGS. 1 and 2, the semiconductor package 1 according to an embodiment may include a first substrate 100, a second substrate 200 mounted on the first substrate 100, a first semiconductor device 300 mounted on the second substrate 200, a second semiconductor device 400 spaced apart from the first semiconductor device 300 in a lateral direction and mounted on the second substrate 200, and a molding member 520 at least partially surrounding the first semiconductor device 300 and the second semiconductor device 400. The second substrate 200 may also be referred to as an interposer.

The semiconductor package 1 according to an embodiment may include the first semiconductor device 300 and the second semiconductor device 400, which perform different functions. One or more first semiconductor devices 300 and one or more second semiconductor devices 400 may be arranged on the second substrate 200. The first semiconductor device 300 and the second semiconductor device 400 may be arranged in parallel with each other in a first horizontal direction (X direction) and a second horizontal direction (Y direction). As shown in FIG. 1, eight first semiconductor devices 300 in total may be arranged around a second semiconductor device 400, but arrangements of the first semiconductor device 300 and the second semiconductor device 400 are not limited thereto.

The first semiconductor device 300 may be configured as a volatile memory chip and/or a nonvolatile memory chip. Examples of the volatile memory chip include dynamic random-access memory (DRAM), static RAM (SRAM), and thyristor RAM (TRAM). Examples of the nonvolatile memory chip include flash memory, magnetic RAM (MRAM), spin-transfer torque MRAM (STT-MRAM), ferroelectric RAM (FRAM), phase change RAM (PRAM), and resistive RAM (RRAM).

According to some embodiments, the first semiconductor device 300 may be configured as a memory chiplet including a plurality of memory chips configured to merge data with each other. Also, the first semiconductor device 300 may include a high bandwidth memory (HBM) chip.

According to some embodiments, the second semiconductor device 400 may be a micro-processor, a graphical processor, a signal processor, a network processor, a chipset, an audio codec, a video codec, an application processor, or a system-on-chip.

The first semiconductor device 300 may include a first base substrate 310, a first intermediate substrate 320, a first upper substrate 320H, a first through electrode 321, a first upper connection pad 322, a first lower connection pad 323, a first internal connection pad 340, a first connection terminal 350, and a first insulating adhesive layer 370.

The first semiconductor device 300 may include a plurality of slices, and each of the plurality of slices may be configured as a plurality of first semiconductor substrates including the first base substrate 310, the first intermediate substrate 320, and the first upper substrate 320H. The plurality of first semiconductor substrates may configure a chip stack and be stacked in a vertical direction (Z direction). The first upper substrate 320H stacked at the top of the plurality of first semiconductor substrates may not include the first through electrode 321. The first base substrate 310 arranged at the bottom of the plurality of first semiconductor substrates may have a planar shape and may be wider than the first intermediate substrate 320. The first insulating adhesive layer 370 insulating and attaching the plurality of first semiconductor substrates to each other may be arranged between the plurality of first semiconductor substrates. A sub-mold member 360 arranged on the first base substrate 310 and surrounding the first intermediate substrate 320 and the first upper substrate 320H may be provided. The first semiconductor device 300 may have a structure in which the plurality of slices are stacked to each operate as a memory chip and to merge data with each other.

Each of the plurality of first semiconductor substrates may include an active surface and an inactive surface that face each other. Here, an inactive surface of the first upper substrate 320H that is an uppermost layer of the plurality of first semiconductor substrates may be a top surface of the first semiconductor device 300 exposed from the molding member 520. Other layers of the plurality of first semiconductor substrates excluding the uppermost layer may include the first through electrode 321 extending therethrough. The first through electrode 321 may be, for example, a through silicon via (TSV).

The first upper connection pad 322 and the first lower connection pad 323 may be electrically connected to each other at the top and bottom of the first through electrode 321. The first lower connection pad 323 may be electrically connected to a first semiconductor wiring layer on the active surface of the plurality of first semiconductor substrates. The first semiconductor wiring layer may be electrically connected to the first connection terminal 350 through a first connection pad 311.

The first internal connection terminal 340 may be between the first upper connection pad 321 and the first lower connection pad 323 between the plurality of first semiconductor substrates. The first upper connection pad 321 and the first lower connection pad 323 located between the plurality of first semiconductor substrates may be electrically connected by the first internal connection terminal 340.

The first connection pad 311 contacting a lowermost layer of the plurality of first semiconductor substrates may electrically connect the first semiconductor device 300 and the second substrate 200 to each other. The first connection terminal 350 may be a solder ball attached to the first connection pad 311.

Through the first connection terminal 350, at least one of a control signal, a power signal, and a ground signal for operations of the first semiconductor device 300 may be received from an external source, a data signal to be stored in the first semiconductor device 300 may be received from an external source, or data stored in the first semiconductor device 300 may be provided to an external source.

The molding member 520 may be provided to at least partially surround the first semiconductor device 300 and the second semiconductor device 400. Here, the molding member 520 may expose top surfaces of the first semiconductor device 300 and the second semiconductor device 400. Accordingly, a top surface of the molding member 520, the top surface of the first semiconductor device 300, and the top surface of the second semiconductor device 400 may be located on a same vertical level. In other words, the top surface of the molding member 520, the top surface of the first semiconductor device 300, and the top surface of the second semiconductor device 400 may be coplanar.

The molding member 520 may protect the first semiconductor device 300 and the second semiconductor device 400 from an external influence, such as an impact or contamination. In this regard, the molding member 520 may include epoxy mold compound or resin. Also, the molding member 520 may be formed through various processes, such as compression molding, lamination, or screen printing.

The second substrate 200 may be arranged below the first semiconductor device 300 and the second semiconductor device 400, and electrically connect the first semiconductor device 300 and the second semiconductor device 400 to each other. According to some embodiments, the second substrate 200 may include a silicon (Si) substrate 210, and may include a rewiring layer arranged on the Si substrate 210. The rewiring layer may include a plurality of rewiring patterns 230 and a rewiring insulating layer 240, and the plurality of rewiring patterns 230 may include a rewiring line pattern 231 and a rewiring via pattern 232.

The second substrate 200 may include a through electrode 220 electrically connected to the rewiring layer and extending into the Si substrate 210, an intermediate connection pad 220B arranged below the Si substrate 210, and electrically connected to the through electrode 220, an intermediate connection pad 220U arranged on the upper surface of the second substrate 200, and an intermediate connection terminal 250 attached to the intermediate connection pad 220B.

The first substrate 100 may be arranged below the second substrate 200 and may be formed to be a printed circuit board, a wafer substrate, a ceramic substrate, or a glass substrate. In the semiconductor package 1 according to an embodiment, the first substrate 100 may be a printed circuit board. The first substrate 100 may include a lower connection pad 120B arranged on a bottom surface of a body portion 110 and an external connection terminal 130 attached to the lower connection pad 120B. An upper connection pad 120U may be arranged on a top surface of the first substrate 100 and electrically connected to the intermediate connection pad 220B of the second substrate 200 through the intermediate connection terminal 250. The semiconductor package 1 may be electrically connected to external devices through the external connection terminal 130.

The second semiconductor device 400 may include a second semiconductor substrate 410, a second connection pad 411, and a second connection terminal 450. The second semiconductor device 400 may include a single slice, and the single slice may be configured as the second semiconductor substrate 410. The second semiconductor substrate 410 may be a wafer and include an active surface and an inactive surface that face each other. Here, the inactive surface of the second semiconductor substrate 410 may be a top surface of the second semiconductor device 400 exposed from the molding member 520.

The second semiconductor substrate 410 may be, for example, an Si wafer including crystalline Si, polycrystalline Si, or amorphous Si. Alternatively, the second semiconductor substrate 410 may include a semiconductor element such as germanium (Ge), or a compound semiconductor such as silicon carbide (SiC), gallium arsenide (GaAs), indium arsenide (InAs), or indium phosphide (InP).

The second semiconductor substrate 410 may have a silicon-on-insulator (SOI) structure. For example, the second semiconductor substrate 410 may include a buried oxide (BOX) layer. According to some embodiments, the second semiconductor substrate 410 may include a conductive area, for example, an impurity-doped well or an impurity-doped structure. Also, the second semiconductor substrate 410 may have any one of various element isolation structures, such as a shallow trench isolation (STI) structure.

A second semiconductor wiring layer may be arranged on the active surface of the second semiconductor substrate 410, and may be electrically connected to the second connection pad 411 on the second semiconductor wiring layer. The second semiconductor substrate 410 may be electrically connected to the second connection terminal 450 through the second connection pad 411. The second connection pad 411 may include, for example, at least one of aluminum (Al), copper (Cu), nickel (Ni), tungsten (W), platinum (Pt), and gold (Au).

The second connection terminal 450 may be arranged to electrically connect the second semiconductor device 400 and the second substrate 200 to each other. The second connection terminal 450 may be a solder ball attached to the second connection pad 411. A material of the solder ball may include at least one of Au, silver (Ag), Cu, tin (Sn), and Al. According to some embodiments, the solder ball may be connected to the second connection pad 411 through one method from among a thermocompression connection and ultrasonic connection, or may be connected to the second connection pad 411 through a thermosonic connection in which the thermocompression connection and the ultrasonic connection are combined. Through the second connection terminal 450, at least one of a control signal, a power signal, and a ground signal for operations of the second semiconductor device 400 may be received from an external source, a data signal to be stored in the second semiconductor device 400 may be received from an external source, or data stored in the second semiconductor device 400 may be provided to an external source.

A package underfill layer 510 includes a vertical underfill layer 510A and a horizontal underfill layer 510B. As shown in FIG. 1, the vertical underfill layer 510A refers to an underfill layer provided in a space between a plurality of semiconductor devices, including the first semiconductor device 300 and the second semiconductor device 400. As shown in FIG. 2, the horizontal underfill layer 510B refers to an underfill layer provided in a space where the second substrate 200 and the plurality of semiconductor devices, including the first semiconductor device 300 and the second semiconductor device 400, are vertically spaced apart from each other. The vertical underfill layer 510A may be referred to as a first underfill layer and the horizontal underfill layer 510B may be referred to as a second underfill layer. The vertical underfill layer 510A and the horizontal underfill layer 510B may be provided as a unitary or integrated object.

The vertical underfill layer 510A may include a first vertical underfill layer 511 provided between the plurality of second semiconductor devices 400 mounted on the second substrate 200, a second vertical underfill layer 512 provided between the first semiconductor device 300 and the second semiconductor device 400, and a third vertical underfill layer 513 provided between the plurality of first semiconductor devices 300 mounted on the second substrate 200. In other words, the vertical underfill layer 510A may be provided as an underfill layer that is arranged in a second gap T2, which is an area between the plurality of semiconductor devices that are separated from each other.

In the semiconductor package 1 according to an embodiment, the first vertical underfill layer 511, the second vertical underfill layer 512, and the third vertical underfill layer 513 may be selectively provided depending on the numbers and arrangements of the first semiconductor devices 300 and the second semiconductor devices 400, and the semiconductor package 1 is not limited by an embodiment. For example, in one variation, when one second semiconductor device 400 is arranged on the second substrate 200, the semiconductor package 1 may not include the first vertical underfill layer 511.

A top surface of the first vertical underfill layer 511, a top surface of the second vertical underfill layer 512, and a top surface of the third vertical underfill layer 513 may have a same vertical level as a top surface of the first semiconductor device 300, a top surface of the second semiconductor device 400, and a top surface of the molding member 520. In other words, the top surfaces of the first vertical underfill layer 511, second vertical underfill layer 512, and third vertical underfill layer 513 may form a same plane or be coplanar with the top surface of the first semiconductor device 300, the top surface of the second semiconductor device 400, and the top surface of the molding member 520. Such a shape is formed because, as will be described below, molding member and package underfill planarization processes are performed after the first vertical underfill layer 511, the second vertical underfill layer 512, and the third vertical underfill layer 513 are formed according to an underfill method in a gap between the plurality of semiconductor devices including the first semiconductor device 300 and the second semiconductor device 400.

The horizontal underfill layer 510B may include a first horizontal underfill layer 514 provided in a gap between the second substrate 200 and the first semiconductor device 300 mounted on the second substrate 200, and a second horizontal underfill layer 515 provided in a gap between the second substrate 200 and the second semiconductor device 400. The horizontal underfill layer 510B may be provided in a first gap T1 that is an area where the plurality of semiconductor devices are vertically spaced apart from the second substrate 200, and may include an underfill side surface 514S that is a side surface exposed between the plurality of semiconductor devices and the second substrate 200. As shown in FIG. 2, the underfill side surface 514S may be exposed in a lateral direction between the first semiconductor device 300 and the second substrate 200. Alternatively, the horizontal underfill layer 510B may include an underfill side surface exposed in a lateral direction between the second semiconductor device 400 and the second substrate 200, depending on the numbers and arrangements of the first semiconductor devices 300 and the second semiconductor devices 400.

While the horizontal underfill layer 510B is formed, a planar shape of a cross-section where the top surface of the second substrate 200 and the horizontal underfill layer 510B are in contact may be greater in width than a width of a planar shape of a cross-section where bottom surfaces of the plurality of semiconductor devices and the horizontal underfill layer 510B are in contact. In other words, the horizontal underfill layer 510B may have a tapered shape in which a horizontal width is increased as the distance between the horizontal underfill layer 510B and the second substrate 200 decreases.

Generally, in a semiconductor package, an underfill extends from side surfaces located on outer edges of a plurality of semiconductor devices to a second substrate. In other words, a package is manufactured while an underfill side surface is in contact with a molding member in a large area. Due to a thermal characteristic difference between the molding member in contact with the underfill side surface and the underfill side surfaces, the molding member in contact with the underfill side surface may be detached. Accordingly, reliability of the semiconductor package may be reduced.

In the semiconductor package 1 according to an embodiment, an area where the horizontal underfill layer 510B included in the package underfill layer 510 is in contact with the molding member 520 may be reduced. In other words, the underfill side surface 514S may be provided in the first gap T1 so as to extend to the top surface of the second substrate 200 from a lower outer boundary LOB where entire outer edges of the plurality of semiconductor devices and the bottom surfaces of the plurality of semiconductor devices meet. Alternatively, the underfill side surface 514S may be provided in the first gap T1 so as to extend to the top surface of the second substrate 200 from the bottom surfaces of the plurality of semiconductor devices adjacent to the lower outer boundary LOB. Accordingly, the reliability of the semiconductor package 1 according to an embodiment may be improved by reducing the area where the underfill side surface 514S and the molding member 520 are in contact.

As the semiconductor package 1 is highly integrated, the second semiconductor device 400, which may include a logic chip, may generate high heat during operation and in response to a power supply. The first semiconductor device 300 spaced apart from the second semiconductor device 400 in a lateral direction also generates heat during operation and in response to a power supply, and thus it is not easy to radiate the heat generated in the second semiconductor device 400 in the lateral direction. Although not illustrated, a heat spreader or the like may be generally provided on the top surfaces of the plurality of semiconductor devices to radiate the heat. In other words, heat may be relatively easily radiated through the top surface of the first semiconductor device 300 and the top surface of the second semiconductor device 400. However, it may be difficult for a portion surrounded by the first semiconductor device 300, the second semiconductor device 400, and the second substrate 200 to radiate heat as the portion is relatively a core of the semiconductor package 1 compared to the top surface of the first semiconductor device 300 and the top surface of the second semiconductor device 400. Similarly, it may be difficult for portions surrounded by the second substrate 200 and between the first semiconductor devices 300 and portions surrounded by the second substrate 200 and between the second semiconductor device 400, which correspond to cores of the semiconductor package 1, to radiate heat.

In the semiconductor package 1 according to an embodiment, the package underfill layer 510 may include an underfill filler, the package underfill layer 510 may include, for example, epoxy resin, and the underfill filler may include a material having a high heat transfer coefficient. In other words, the underfill filler included in the package underfill layer 510 may include boron nitride (BN) or aluminum nitride (AlN). Alternatively, the underfill filler included in the package underfill layer 510 may include silica coated aluminum nitride (SCAN). Thermal conductivity of the underfill filler including BN may be about 250 W/mK to about 300 W/mK. Thermal conductivity of the underfill filler including SCAN may be about 160 W/mK to about 260 W/mK.

The molding member 520 may include a mold filler. A general mold member uses epoxy molding compound (EMC) that is a thermosetting resin. However, the EMC may have a limitation on thermal conductivity. In other words, the total thermal conductivity of the molding member 520 including EMC may be difficult to exceed 5 W/mK even when 90% or more of an organic filler that may be included in the molding member 520 is applied by configuring the high conductivity organic filler with a material having a thermal conductivity reaching 100 W/mK.

The underfill filler of the package underfill layer 510 may include a material having higher thermal conductivity than the mold filler, and thus the package underfill layer 510 may have relatively high thermal conductivity compared to the molding member 520. The package underfill layer 510 having high thermal conductivity may be provided between the plurality of semiconductor devices, thereby smoothly radiating heat generated in the semiconductor package 1 through the package underfill layer 510. Accordingly, a thermal characteristic of the semiconductor package 1 according to an embodiment may be increased or improved.

The package underfill layer 510 may be provided between the plurality of semiconductor devices and the horizontal underfill layer 510B may be provided between the second substrate 200 and the plurality of semiconductor devices, and at the same time, a distance between the first gap T1 and the second gap T2 may be appropriately adjusted so as to reduce a surface area where the underfill side surface 514S is in contact with the molding member 520. For example, a first separation width, which is a distance of the first gap T1, may be greater than a second separation width, which is a distance of the second gap T2.

The package underfill layer 510 may be formed through a capillary method. When the first separation width is less than the second separation width, an underfill layer may be formed up to the first gap T1, but it may not be easy for an underfill material introduced to the first gap T1 to fill or be in the second gap T2 by being introduced to the second gap T2. Accordingly, the first separation width, which is a distance of the first gap T1 may be greater than the second separation width, which is a distance of the second gap T2.

The first separation width and the second separation width may be suitably adjusted for the package underfill layer 510 of the semiconductor package 1. For example, the first separation width may be about 40 μm to about 60 μm, and the second separation width may be about 20 μm to about 30 μm.

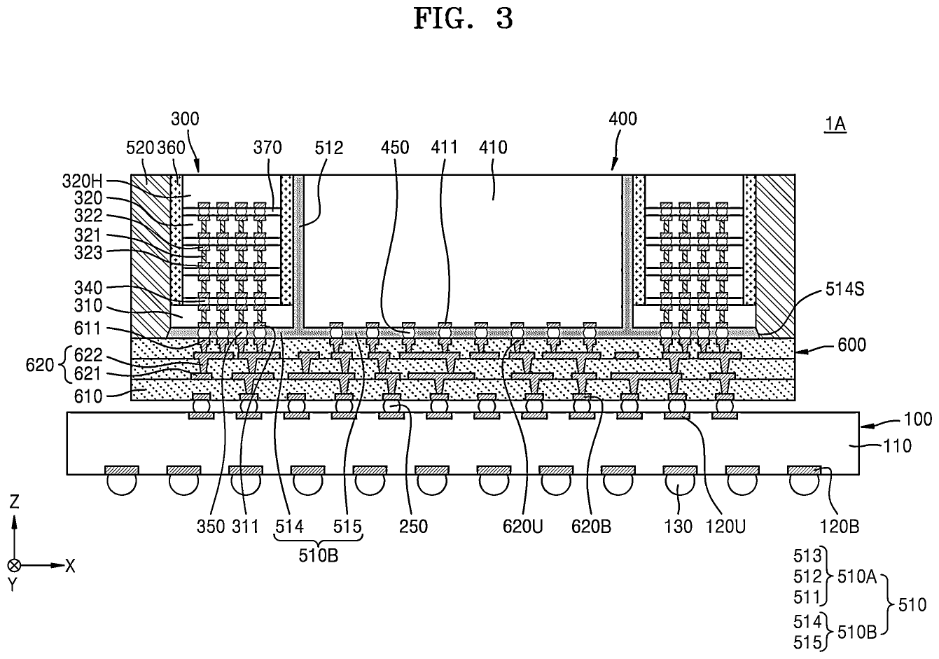

FIG. 3 is a cross-sectional view of a semiconductor package 1A according to an embodiment. Descriptions that are the same as those provided above may be omitted.

Referring to FIG. 3, the semiconductor package 1A according to an embodiment may include the first substrate 100, a second substrate 600 mounted on the first substrate 100, the first semiconductor device 300 mounted on the second substrate 600, the second semiconductor device 400 spaced apart from the first semiconductor device 300 in a lateral direction and mounted on the second substrate 600, and the molding member 520 surrounding the first semiconductor device 300 and the second semiconductor device 400. The second substrate 600 may also be referred to as a rewiring interposer.

According to some embodiments, the second substrate 600 may be formed through a rewiring process. The second substrate 600 may include a rewiring insulating layer 610 and a plurality of rewiring patterns 620. The rewiring insulating layer 610 may at least partially surround the plurality of rewiring patterns 620. According to some embodiments, the second substrate 600 may include a plurality of rewiring insulating layers 610 that are stacked on each other. For example, a first rewiring insulating layer adjacent to the first semiconductor device 300 and the second semiconductor device 400, and a second rewiring insulating layer below the first rewiring insulating layer may be provided. Additionally, two or more rewiring insulating layers 610 may be included in the second substrate 600.

The rewiring insulating layer 610 may be formed from, for example, a material including an organic compound. According to some embodiments, at least one lower rewiring insulating layer 610 may be formed from a material layer including an organic polymer material. According to some embodiments, the rewiring insulating layer 610 may be formed from photosensitive polyimide (PSPI). The rewiring insulating layer 610 may include photo imagable dielectric material. The rewiring insulating layer 610 may include, for example, photosensitive polymer. Photosensitive polymer may include, for example, PSPI, polybenzoxazole, phenol-based polymer, or benzocycloebutene-based polymer.

The plurality of rewiring patterns 620 may include a plurality of rewiring line patterns 621 and a plurality of rewiring via patterns 622. The plurality of rewiring patterns 620 may include, for example, a metal such as Cu, Al, W, titanium (Ti), tantalum (Ta), indium (In), molybdenum (Mo), manganese (Mn), cobalt (Co), Sn, Ni, magnesium (Mg), rhenium (Re), beryllium (Be), gallium (Ga), or ruthenium (Ru), or an alloy thereof, but is not limited thereto.

The plurality of rewiring line patterns 621 may be arranged on at least one of a top surface and a bottom surface of the rewiring insulating layer 610. The plurality of rewiring via patterns 622 may be connected to some of the plurality of rewiring line patterns 621 by extending through the rewiring insulating layer 610. The plurality of rewiring via patterns 622 may have a tapered shape having a horizontal width that decreases as a distance between the rewiring via patterns 622 and the first semiconductor device 300 increases.

According to some embodiments, some of the plurality of rewiring line patterns 621 and some of the plurality of rewiring via patterns 622 may be formed together to be integrated. For example, the rewiring line pattern 621 and a rewiring via pattern 622 in contact with a bottom surface of the rewiring line pattern 621 may be formed together to be integrated.

According to some embodiments, at least a portion of an uppermost rewiring line pattern 621 may be an upper intermediate connection pad 620U at which the first connection terminal 350 and the second connection terminal 450 is attached. At least a portion of a lowermost rewiring line pattern 621 may be a lower intermediate connection pad 620B at which the intermediate connection terminal 350 is attached.

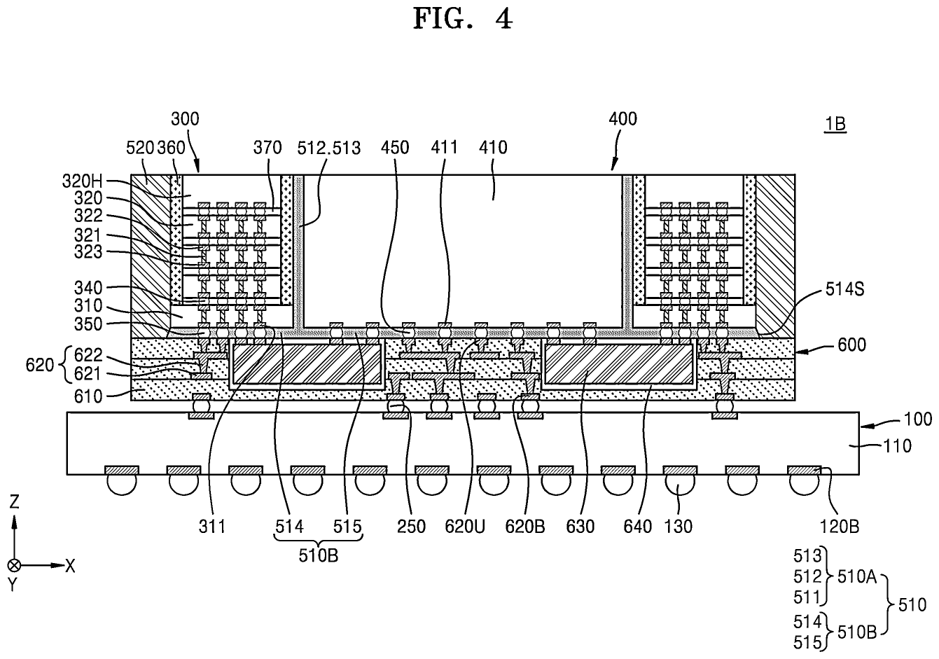

FIG. 4 is a cross-sectional view of a semiconductor package 1B according to an embodiment. Descriptions that are the same as those provided above may be omitted.

Referring to FIG. 4, the second substrate 600 may further include a bridge chip 630. The bridge chip 630 may be arranged in a cavity 640 defined by the rewiring insulating layer 610 of the second substrate 600. The bridge chip 630 may electrically connect the plurality of semiconductor devices including the first semiconductor device 300 and the second semiconductor device 400 to each other. The bridge chip 630 included in the second substrate 600 may correspond to input/output (I/O) density of the plurality of semiconductor devices mounted on the second substrate 600 corresponding to the rewiring interposer of FIG. 3, and may be used to increase an electric signal characteristic between the plurality of semiconductor devices.

In one variation, an adhesive material for arranging the bridge chip 630 may be in the cavity 640. Also, for example, in FIG. 4, the rewiring insulating layer 610 covers or overlaps a bottom surface of the bridge chip 630, which faces the first substrate 100. In one variation, the bottom surface of the bridge chip 630 may be exposed towards the first substrate 100 from the rewiring insulating layer 610.

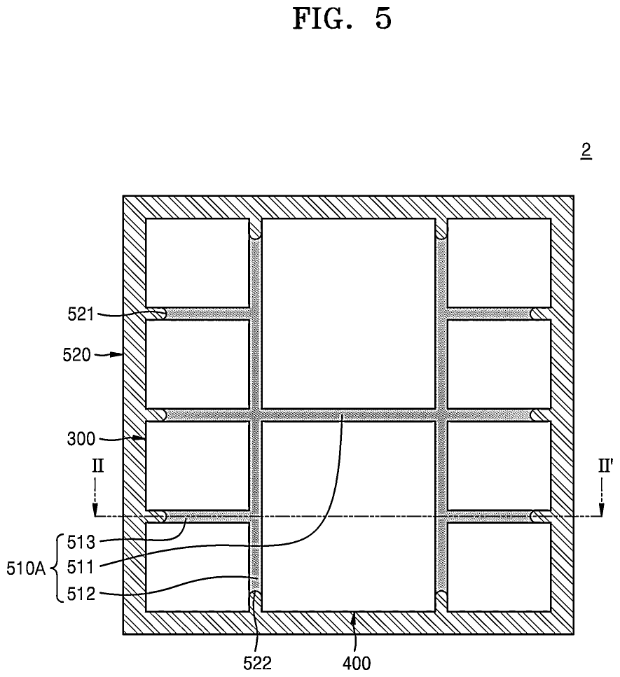

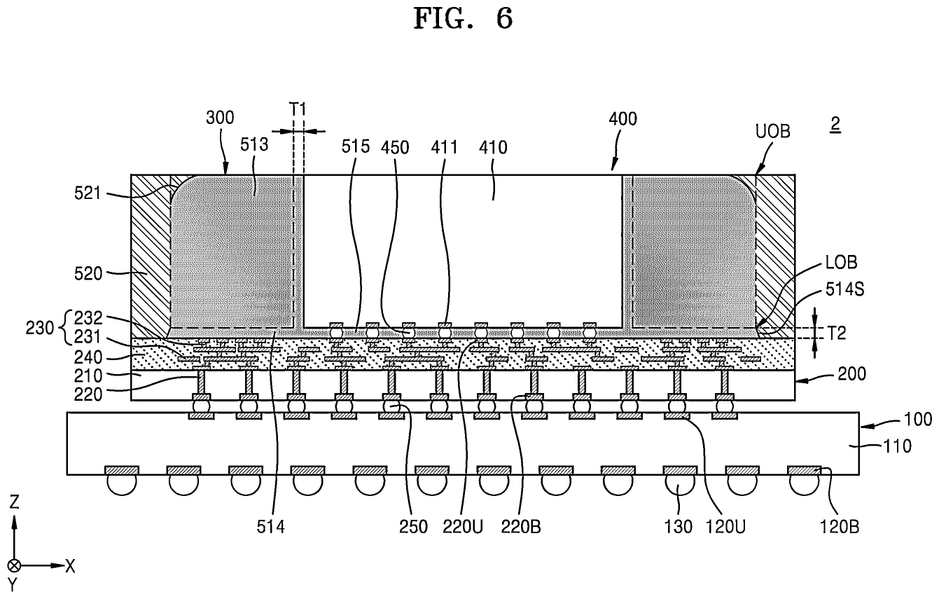

FIG. 5 is a plane layout of a semiconductor package 2 according to an embodiment. FIG. 6 is a cross-sectional view of the semiconductor package 2 of FIG. 5 taken along a line II-II′ of FIG. 5 according to an embodiment. Descriptions that are the same as those provided above may be omitted. In FIG. 6, broken lines on the left and right of the second semiconductor device 400 denote the adjacent first semiconductor device 300 from the cross-sectional view taken along the line II-II′.

The molding member 520 may be partially recessed towards the vertical underfill layer 510A at an edge portion of the second gap T2 adjacent to an upper outer boundary UOB where the entire outer edges of the plurality of semiconductor devices and the top surfaces of the plurality of semiconductor devices meet. The vertical underfill layer 510A is formed in addition to the horizontal underfill layer 510B provided between the second substrate 200 and the plurality of semiconductor devices, and thus a total amount of the package underfill layer 510 of the semiconductor package 2 according to an embodiment is greater compared to when there is only the horizontal underfill layer 510B. Accordingly, while the package underfill layer 510 is formed, the vertical underfill layer 510A may be recessed towards an inner side of the second gap T2. A degree and shape of the vertical underfill layer 510A recessed at the edge portion of the second gap T2 adjacent to the upper outer boundary UOB may vary according to the amount, property, or the like of a material forming an underfill layer.

For example, as shown in FIG. 5, the third vertical underfill layer 513 may be formed between the plurality of first semiconductor devices 300 and the molding member 520 may be recessed in a central direction of the semiconductor package 2, thereby forming a first recess molding 521. Similarly, the second vertical underfill layer 512 may be formed between the first semiconductor device 300 and the second semiconductor device 400 and the molding member 520 may be recessed in a central direction of the semiconductor package 2, thereby forming a second recess molding 522. As described above, recessed degrees and shapes of the first recess molding 521 and the second recess molding 522 may vary according to the amount, property, or the like of the material forming the underfill layer.

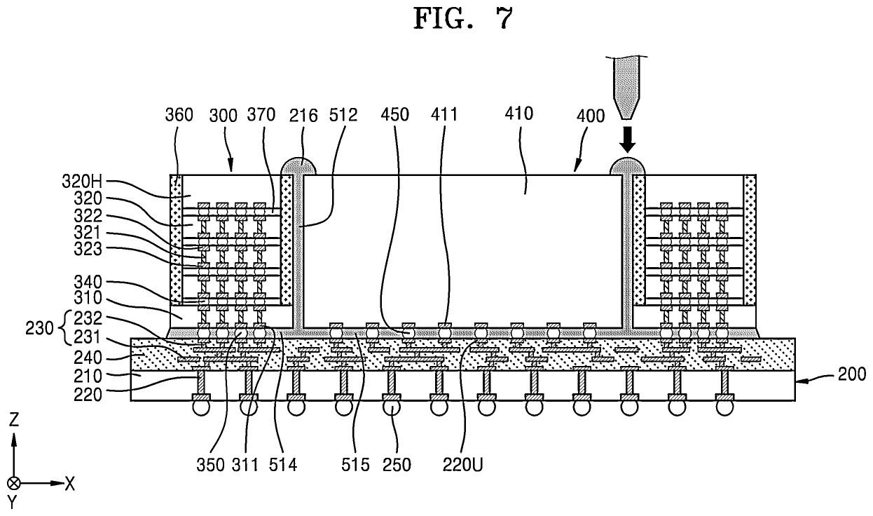

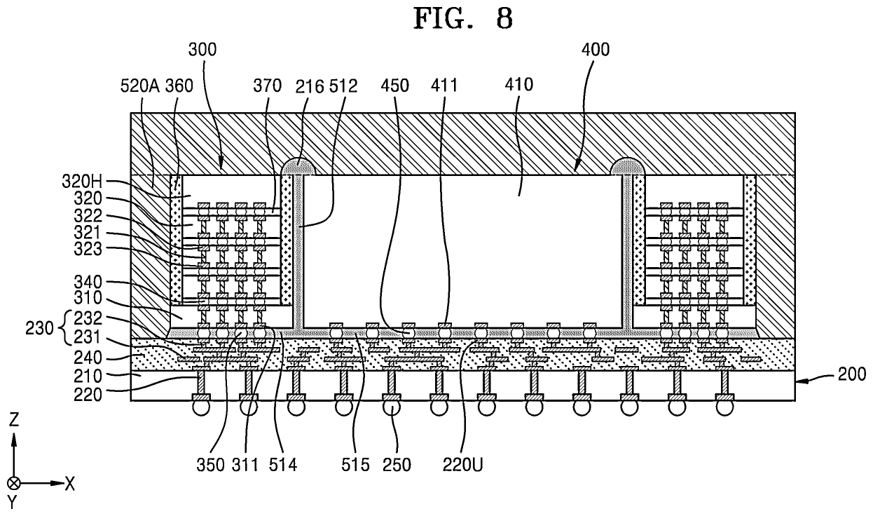

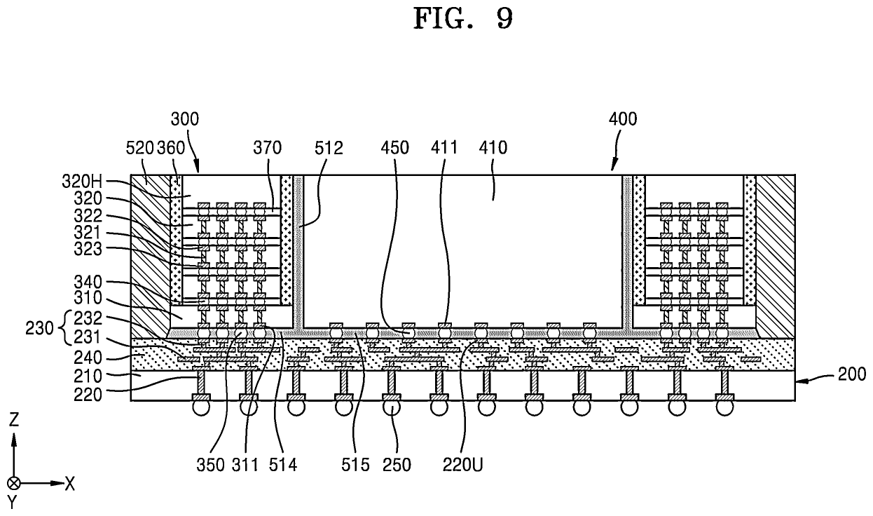

FIG. 7 is a view for describing a method of manufacturing the semiconductor package 1, according to an embodiment. FIG. 8 is a view for describing a method of manufacturing the semiconductor package 1, according to an embodiment. FIG. 9 is a view for describing a method of manufacturing the semiconductor package 1, according to an embodiment. Descriptions that are the same as those provided above may be omitted.

Referring to FIG. 7, a package underfill layer of the semiconductor package 1 may be formed as an underfill material is introduced to a first gap of a plurality of semiconductor devices. Because the underfill material is provided to the first gap, the underfill material may remain and form a remaining portion 216.

Referring to FIG. 8, a molding member 520A may be formed on a process resultant of FIG. 7. The molding member 520A may cover or overlap the top of the first semiconductor device 300 and the top surface of the second semiconductor device 400. Accordingly, the remaining portion 216 may be at least partially surrounded by the molding member 520A. A portion of the molding member 520A and the remaining portion 216 may be removed along broken lines extending in the top surfaces of the first semiconductor device 300 and the second semiconductor device 400. In FIG. 8, the top surface of the first semiconductor device 300 and the top surface of the second semiconductor device 400 are on a same vertical level, but in one variation, the top surface of the first semiconductor device 300 and the top surface of the second semiconductor device 400 may have different vertical levels.

Referring to FIG. 9, the portion of the molding member 520A and the remaining portion 216 may be removed from a process resultant of FIG. 8. Thus, as described above, the top surface of the first vertical underfill layer 511, the top surface of the second vertical underfill layer 512, and the top surface of the third vertical underfill layer 513 may have a same vertical level as the top surface of the first semiconductor device 300, the top surface of the second semiconductor device 400, and the top surface of the molding member 520.

Hereinabove, the embodiments have been described with reference to the accompanying drawings, but it will be understood by one of ordinary skill in the art that the present disclosure may be executed in other specific forms without changing technical ideas or essential features. Accordingly, the embodiments described above are examples in all aspects and should not be construed as being limited.

What is claimed is:

1. A semiconductor package comprising:
an interposer;
a plurality of semiconductor devices that are on the interposer and spaced apart from each other; and
a package underfill layer that comprises a first underfill layer in a first gap that is between the plurality of semiconductor devices and a second underfill layer in a second gap that is between the plurality of semiconductor devices and the interposer,
wherein the second underfill layer comprises a second underfill layer side surface that faces a lateral direction, wherein the second underfill layer side surface does not contact the plurality of semiconductor devices and a portion of the interposer that is adjacent to the second gap,
wherein the second underfill layer side surface extends between a top surface of the interposer and bottom surfaces of the plurality of semiconductor devices and extends from a lower outer boundary, and wherein the lower outer boundary corresponds to a location in which outer side surfaces of the plurality of semiconductor devices and the bottom surfaces of the plurality of semiconductor devices meet.

2. The semiconductor package of claim 1, wherein a top surface of the first underfill layer is exposed in the first gap, and wherein top surfaces of the plurality of semiconductor devices are coplanar.

3. The semiconductor package of claim 2, wherein the top surface of the first underfill layer and the top surfaces of the plurality of semiconductor devices are coplanar.

4. The semiconductor package of claim 2, further comprising a mold member that is on the top surface of the interposer and at least partially surrounds outer edges of the plurality of semiconductor devices, wherein a top surface of the mold member, the top surface of the first underfill layer exposed in the first gap, and the top surfaces of the plurality of semiconductor devices are coplanar.

5. The semiconductor package of claim 4, wherein the mold member contacts an entirety of the outer side surfaces of the plurality of semiconductor devices, and wherein the first underfill layer and the second underfill layer are unitary.

6. The semiconductor package of claim 5, wherein the second underfill layer side surface and the mold member contact each other at the lower outer boundary.

7. The semiconductor package of claim 5, wherein the second underfill layer side surface and the mold member contact each other at the bottom surfaces of the plurality of semiconductor devices.

8. The semiconductor package of claim 5, wherein the package underfill layer further comprises an underfill filler, wherein the mold member further comprises a mold filler, and a thermal conductivity of the underfill filler is greater than a thermal conductivity of the mold filler.

9. The semiconductor package of claim 8, wherein the underfill filler comprises boron nitride (BN), aluminum nitride (AlN), or silica coated aluminum nitride (SCAN), and the thermal conductivity of the underfill filler is about 160 W/mK to about 300 W/mK.

10. The semiconductor package of claim 1, wherein the plurality of semiconductor devices comprise a first semiconductor device and a second semiconductor device, wherein the first semiconductor device comprises a logic chip, and wherein the second semiconductor device comprises a plurality of stacked memory chips.

11. The semiconductor package of claim 1, wherein the interposer comprises a semiconductor substrate and a plurality of through electrodes that extend into the semiconductor substrate.

12. The semiconductor package of claim 1, wherein the interposer is a rewiring interposer that comprises a plurality of rewiring patterns and a plurality of insulating layers.

13. The semiconductor package of claim 12, wherein the rewiring interposer defines a cavity in the plurality of insulating layers, and wherein a bridge chip is in the cavity and is electrically connected to some of the plurality of semiconductor devices.

14. The semiconductor package of claim 4, wherein the mold member is recessed at an edge portion of the first gap, wherein the edge portion of the first gap is adjacent to an upper outer boundary, and wherein the upper outer boundary corresponds to a location in which the top surfaces of the plurality of semiconductor devices and the outer side surfaces of the plurality of semiconductor devices meet.

15. The semiconductor package of claim 4, wherein a first separation width that corresponds to a distance between the plurality of semiconductor devices is greater than a second separation width that corresponds to a distance between the plurality of semiconductor devices and the interposer.

16. The semiconductor package of claim 15, wherein the first separation width is about 40 μm to about 60 μm, and wherein the second separation width is about 20 μm to about 30 μm.

17. A semiconductor package comprising:
an interposer that comprises a semiconductor substrate, a plurality of through electrodes that extend into the semiconductor substrate, and a rewiring layer;
a plurality of semiconductor devices that are on the interposer and spaced apart from each other;
a package underfill layer that comprises a first underfill layer in a first gap that is between the plurality of semiconductor devices and a second underfill layer in a second gap that is between the plurality of semiconductor devices and the interposer; and
a mold member that is on a top surface of the interposer and at least partially surrounds outer side surfaces of the plurality of semiconductor devices,
wherein the second underfill layer comprises a second underfill layer side surface that faces a lateral direction, wherein the second underfill layer side surface does not contact the plurality of semiconductor devices and a portion of the interposer that is adjacent to the second gap,
wherein the second underfill layer side surface extends between the top surface of the interposer and bottom surfaces of the plurality of semiconductor devices and extends from a lower outer boundary, and wherein the lower outer boundary corresponds to a location in which the outer side surfaces of the plurality of semiconductor devices and the bottom surfaces of the plurality of semiconductor devices meet, and
wherein the plurality of semiconductor devices comprise a first semiconductor device and a second semiconductor device, wherein the first semiconductor device comprises a logic chip, and wherein the second semiconductor device comprises a plurality of stacked memory chips.

18. The semiconductor package of claim 17, wherein a width of the second underfill layer increases as a distance between the second underfill layer and the interposer decreases.

19. The semiconductor package of claim 18, wherein the mold member is recessed at an edge portion of the first gap, wherein the edge portion of the first gap is adjacent to an upper outer boundary, and wherein the upper outer boundary corresponds to a location in which top surfaces of the plurality of semiconductor devices and the outer side surfaces of the plurality of semiconductor devices meet.

20. A semiconductor package comprising:
an interposer that comprises a semiconductor substrate, a plurality of through electrodes that extend into the semiconductor substrate, and a rewiring layer;
a plurality of semiconductor devices that are on the interposer and spaced apart from each other;
a package underfill layer that comprises a first underfill layer in a first gap that is between the plurality of semiconductor devices and a second underfill layer in a second gap that is between the plurality of semiconductor devices and the interposer; and
a mold member that is on a top surface of the interposer and at least partially surrounds outer side surfaces of the plurality of semiconductor devices,
wherein the second underfill layer comprises a second underfill layer side surface that faces a lateral direction, wherein the second underfill layer side surface does not contact the plurality of semiconductor devices and a portion of the interposer in the second gap,
the second underfill layer side surface extends between the top surface of the interposer and bottom surfaces of the plurality of semiconductor devices and extends from a lower outer boundary, and wherein the lower outer boundary corresponds to a location in which the outer side surfaces of the plurality of semiconductor devices and the bottom surfaces of the plurality of semiconductor devices meet,
wherein a top surface of the mold member, a top surface of the first underfill layer that is exposed in the first gap, and the top surfaces of the plurality of semiconductor devices are coplanar,
wherein the mold member contacts an entirety of the outer side surfaces of the plurality of semiconductor devices, wherein the first underfill layer and the second underfill layer are unitary,
wherein the package underfill layer comprises an underfill filler, wherein the underfill filler comprises boron nitride (BN) or silica coated aluminum nitride (SCAN),
wherein a first separation width corresponds to a distance between the plurality of semiconductor devices, wherein the first separation width is greater than a second separation width that corresponds to a distance between the plurality of semiconductor devices and the interposer, and
wherein the plurality of semiconductor devices comprise a first semiconductor device and a second semiconductor device, wherein the first semiconductor device comprises a logic chip, and wherein the second semiconductor device comprises a plurality of stacked memory chips.
